(19) United States
(12) Patent Application Publication
(10) Pub. No.: US 2025/0229362 A1
(43) Pub. Date: Jul. 17, 2025

(54) METHOD OF RUNNING A LASER SYSTEM, LASER SYSTEM AND EVAPORATION SYSTEM

(71) Applicant: MAX-PLANCK-GESELLSCHAFT ZUR FÖRDERUNG DER WISSENSCHAFTEN E.V., München (DE)

(72) Inventor: Wolfgang BRAUN, Bietingheim-Bissingen (DE)

(21) Appl. No.: 18/703,942

(22) PCT Filed: May 25, 2022
(86) PCT No.: PCT/EP2022/064305

§ 371 Date: Apr. 23, 2024

(51) Int. Cl. B23K 26/352; B23K 26/06; B23K 26/40; B23K 26/70

(52) U.S. Cl. CPC B23K 26/352; B23K 26/0643; B23K 26/0648; B23K 26/40; B23K 26/703

(57) ABSTRACT

The invention relates to a method of running a laser system (10) for providing a laser beam (20) capable of heating and/or evaporating and/or sublimating a target (120) located in a reaction chamber (110) of an evaporation system (100), the laser system (10) comprising a laser light source (12) for providing a laser beam (20), and beam adjusting means (40) for adjusting at least the cross section (22) of the laser beam (20), the beam adjusting means (40) comprising along the laser beam (20) a first adjusting section (42), a clipping aperture (70) with a clipping opening (72) and a second adjusting section (44). Further, the invention relates to a laser system (10) for heating and/or evaporating and/or sublimating a target (120) located in a reaction chamber (110) of an evaporation system (100), the laser system (10) comprising a laser light source (12) for providing a laser beam (20), wherein the laser system (10) comprises beam adjusting means (40) comprising along the laser beam (20) a first adjusting section (42), a clipping aperture (70) with a clipping opening (72) and a second adjusting section (44). Additionally, the invention relates to an evaporation system (100) for coating a substrate (126) with evaporated and/or sublimated material of a source (124), comprising a reaction chamber (110) with a reaction volume (112) for arranging the source (124) and the substrate (126), and a substrate (126) laser system (10) for heating the substrate (126) and/or a source (124) laser system (10) for evaporating and/or sublimating material of the source (124).

The invention relates to a method of running a laser system for providing a laser beam capable of heating and/or evaporating and/or sublimating a target located in a reaction chamber of an evaporation system, the laser system comprising a laser light source for providing a laser beam, and beam adjusting means for adjusting at least the cross section of the laser beam, the beam adjusting means comprising along the laser beam a first adjusting section, a clipping aperture with a clipping opening and a second adjusting section. Further, the invention relates to a laser system for heating and/or evaporating and/or sublimating a target located in a reaction chamber of an evaporation system, the laser system comprising a laser light source for providing a laser beam, wherein the laser system comprises beam adjusting means comprising along the laser beam a first adjusting section, a clipping aperture with a clipping opening and a second adjusting section. Additionally, the invention relates to an evaporation system for coating a substrate with evaporated and/or sublimated material of a source, comprising a reaction chamber with a reaction volume for arranging the source and the substrate, and a substrate laser system for heating the substrate and/or a source laser system for evaporating and/or sublimating material of the source.

In evaporation systems, in particular used for thermal laser epitaxy (TLE), surfaces of either substrates or sources preferably are heated by laser radiation. For sources the irradiation usually takes place at an angle to the surface normal, for substrates, where the back side of the wafer is heated, normal incidence is ideal.

Especially in TLE, the power density needed for evaporating and/or sublimating different materials can also be extremely different. For instance, some source materials require 1 W, others more than 500 W when evaporated with the same laser in the same geometry. In the case of substrate heating, it is beneficial to be able to heat substrates with very different sizes, for instance between 5 mm and 100 mm diameter or side length, resulting in a factor of 400 in area. Also, substrates with different materials are possible requiring a factor of more than 100 in laser power density (intensity per area) for their optimum process temperatures, respectively.

It is therefore desirable, especially for TLE applications, to be able to control heating lasers with dynamical ranges of at least 1000, if not more. Lasers, however, have a threshold, which means they turn on abruptly at a certain amount, often about 3% or even higher, of their maximal intensity. It is therefore not straightforward to achieve a dynamical range, e.g. a ratio between lowest and highest controllable intensity, of more than 30.

A known solution for this demand is a pulsed operation of the laser, adjusting the time-averaged power by pulse width modulation. Pulse width modulation, however, is detrimental as it produces a strongly time-varying signal, and even with multi-kHz repetition frequencies, regularly leads to excessive thermal strain and substrate failure.

In view of the above, it is an object of the present invention to provide an improved method of running a laser system, an improved laser system and an improved evaporation system which do not have the aforementioned drawbacks of the state-of-the-art. In particular it is an object of the present invention to provide an improved method of running a laser system, an improved laser system and an improved evaporation system which allow varying the power density of a laser light provided by a laser light source provided at a surface of a target, in particular providing a dynamical range of the power density between the lowest providable power density and the highest providable power density of 1000 or more.

This object is satisfied by the respective independent patent claims. In particular, this object is satisfied by a method of running a laser system according to claim 1, by a laser system according to claim 8 and by an evaporation system according to claim 26. The dependent claims describe preferred embodiments of the invention. Details and advantages described with respect to a method of running a laser system according to the first aspect of the invention also refer to a laser system according to the second aspect of the invention, and to an evaporation system according to the third aspect of the invention and vice versa, if of technical sense.

According to the first aspect of the invention, the object is satisfied by a method of running a laser system for providing a laser beam capable of heating and/or evaporating and/or sublimating a target located in a reaction chamber of an evaporation system, the laser system comprising a laser light source for providing a laser beam, and beam adjusting means for adjusting at least the cross section of the laser beam, the beam adjusting means comprising along the laser beam a first adjusting section, a clipping aperture with a clipping opening and a second adjusting section.

The inventive method comprises the steps of:
a) Determining a desired power of the laser beam and a desired cross section of the laser beam to be provided at the surface of the target,
b) Setting the laser light source for providing the laser beam with an initial power and an initial cross section,
c) Setting the first adjusting section and/or the clipping opening based on the initial power, the initial cross section and the desired power, for providing the laser beam after shining through the clipping opening with an intermediate power matched to the desired power,
d) Setting the second adjusting section for providing the laser beam with the desired power and the desired cross section at the surface of the target, and
e) Providing the laser beam by the laser light source set in step b), and subsequently adjusting the laser beam by the beam adjusting means set in steps c) and d) for providing the laser beam with the desired power and the desired cross section, respectively, set in step a) at the surface of the target.

The method according to the present invention allows running a laser system, preferably a laser system used in an evaporation system, in particular for TLE application. The laser system provides a laser beam, again preferably used in said evaporation system. The laser beam can be used for evaporating and/or sublimating a target, for example the material of a source. Alternatively, or additionally, the laser beam can also be used only for heating a target, for instance a substrate to be coated with evaporated and/or sublimated material of the source.

In addition to the laser light source, the laser system comprises beam adjusting means for changing properties of the laser beam, in particular for changing at least a cross section of the laser beam. The beam adjusting means has three compulsory parts, in particular along the direction of the laser beam a first adjusting section, a clipping aperture, and a second adjusting section, respectively. The clipping aperture comprises a clipping opening, preferably centered to the laser beam. The material of the clipping aperture is preferably opaque or at least essentially opaque for the laser beam. Hence, the clipping aperture can cut the laser beam very effectively.

The method according to the present invention is intended for providing a laser beam with a wide range of possible power densities at the target. In particular, the method according to the present invention is capable of providing a laser beam with a desired power density at the target. The steps necessary for this task are described in the following.

In a first step a) of the method according to the present invention, a desired power density needed at the target is determined. A power density is composed of the irradiated power and the surface onto which it is irradiated. In particular, the irradiated power divided by the irradiated surface equals the power density. Hence, in step a) of the method according to the present invention the desired power of the laser beam and the desired cross section of the laser beam to be provided at the surface of the target are determined. In other words, after step a) has been carried out, information is available as to what properties, in particular what power density, the laser beam should have at the location of the target.

The following step b) comprises the preparation of an operation of the laser light source. In particular, the laser light laser beam is set such that it will provide a laser beam with an initial power and an initial cross section. Again, the initial power and the initial cross section define an initial power density. The initial power or the initial cross section, in particular both of them, can preferably be set based on the desired power and/or desired cross section determined in step a). This allows minimizing the modifications and adjustments needed to be carried out by the beam adjustment needs for providing the laser beam with the desired power and desired cross section at the target. Additionally, setting the initial power and/or initial cross sections to different values contributes to the variation range of the power density providable by the laser system run by the method according to the present invention.

In the third step c), the key part of the adjustment of the laser beam is prepared.

Within the adjustment means, the laser beam passes first through the first adjusting section and then through the clipping aperture. The first adjustment section can at least alter a cross section of the laser beam. In other words, as the total power of the laser beam essentially stays constant at the initial power set by the laser light source, the alterations of the cross section of the laser beam provided by the first adjustment section essentially set the power density of the laser beam impinging onto the clipping aperture. Thereby, the laser power impinging and consequently shining through the clipping opening can be adjusted.

Additionally, or alternatively, the clipping aperture, in particular its clipping opening, itself has a strong influence on a size of the fraction of the laser beam still available after the clipping aperture.

Hence, by both altering the size of the cross section of the laser beam impinging onto the clipping aperture, and altering the size of the clipping aperture, respectively, the amount of laser power still comprised by the laser beam after the clipping aperture can be adjusted.

In step c), the first adjustment section and/or the clipping opening is set in a way that said power comprised by the laser beam after the clipping aperture is an intermediate power matched to the desired power determined in step a). In the sense of the present invention, the intermediate power is chosen such that it can be ensured that the laser beam comprises at least, preferably exactly, the desired power at the target. Hence, the intermediate power preferably is chosen slightly larger than the desired power for compensating power losses between the clipping aperture and the target.

The next step d) concerns the second adjustment section. After the clipping aperture, the laser beam comprises the intermediate power and the cross section of the laser beam is defined by the size and cross section of the clipping aperture. Hence, the second adjusting section is primarily used for altering the cross section of the laser beam from said size of the clipping aperture to the desired cross section of the laser beam at the target. As mentioned above, possible power losses of the laser beam between the clipping aperture and the target can be already be addressed by accordingly setting the intermediate power.

In summary, after step d) the complete laser system, including in particular the laser light source, the first adjusting section, the clipping aperture, and the second adjusting section, respectively, are readily set for providing the laser beam with the desired power and the desired cross section, and hence with a desired power density, at the target.

Consequently, after completion of the setting procedure of steps b), c) and d), respectively, in the last compulsory step e) of the method according to the present invention the laser beam is actually provided at the target with both, the desired power and the desired cross section, respectively, and hence with the desired power density. By the interplay in particular of the variations of laser power and cross section already providable by the laser light source and the possibility of huge variations of the laser power remaining after the clipping aperture, a dynamical range of the power density between the lowest providable power density and the highest providable power density of 1000 or more can easily be provided. For instance for circular cross sections and clipping openings, a variation of the radius of said cross section or opening by a factor of two leads to a variation of the respective area, and hence of the power density, with a factor of four. In particular, said variations of the laser power remaining after the clipping aperture are essentially limited only by the beam expansion capabilities of the first adjusting section and size limits for the clipping opening due to manufacturing accuracy and integral stability of the clipping aperture.

Further, the method according to the present invention can be characterized in that the intermediate power of the laser beam provided after the clipping opening corresponds to a sum of the desired power and expected power losses in the second adjusting section. As mentioned above, the intermediate power is chosen such that a laser beam comprises at least the desired power when irradiating the target. By setting the intermediate power to the sum of the desired power and expected power losses in the second adjusting section, a power of the laser beam at the target of exactly the desired power can be provided and an irradiation of the target with excess power can be avoided.

In addition, the method according to the present invention can comprise that in step b) the initial power is set between 10% and 100%, in particular 5% and 100, preferably 3% and 100%, of a maximum power providable by the laser light source. By that already the laser light source can contribute to the range of providable power densities a factor of 10, in particular 20, preferably more than 30.

According to an embodiment of the method according to the present invention, in step c) the first adjusting section is set to enlarge the cross section of the laser beam for reducing the fraction of the laser shining through the clipping opening. The maximum of laser power shining through the clipping opening of the clipping aperture can be achieved by providing a focused laser beam which completely shines through the clipping opening. By enlarging the cross section of the laser beam by the first adjusting section, the total power of the laser beam is spread over a larger area. Simultaneously, the fraction of the laser beam impinging on the bulk of the clipping aperture and thereby missing the clipping aperture rises with the size of the cross section of the laser beam. Hence, by altering the cross section of the laser beam by the first adjusting section changing the provided final power at the target can easily be adjusted.

Additionally, or alternatively, the method can be characterized in that in step c) the clipping aperture is set to reduce the clipping opening for reducing the fraction of the laser beam shining through the clipping opening. As already mentioned above, the maximum of laser power shining through the clipping opening of the clipping aperture can be achieved by providing a focused laser beam which completely shines through the clipping opening. By reducing size of the clipping opening, the fraction of the laser beam shining through the clipping opening can likewise be reduced. Hence, by altering the size of the clipping opening changing the provided final power at the target can easily be adjusted.

Preferably, the method according to the present invention comprises both possibilities described above, namely adjusting the cross section of the laser beam impinging onto the clipping aperture by the first adjusting section, and adjusting the size of the clipping opening, respectively. The effects of both measures on the providable final power add up, preferably multiply.

In particular, the method according to the present invention can be enhanced by that the fraction of the laser beam shining through the clipping opening is provided between 100% and less than 3%, in particular 100% and less than 2%, preferably 100% and less than 1%, of the laser beam impinging on the clipping aperture. As already described, said fraction can be altered by adjusting the cross section of the laser beam impinging onto the clipping aperture and/or by adjusting the size of the clipping opening. By that the beam adjusting means, in particular the first adjusting section and the clipping aperture, contribute to the range of providable power densities a factor of more than 30, in particular more than 50, preferably more than 100.

Considering that also the laser light source can contribute to the range of providable power densities a factor of 10, in particular 20, preferably more than 30, a total range of providable power densities of a factor of more than 300 up to preferably more than 3000 can be provided by running a laser system by a method according to the present invention.

In addition, the method can be enhanced further in that in an additional step f) the power and/or the cross section of the laser beam provided in step e) are monitored and compared to the desired power and/or the desired cross section, respectively, and wherein the result of said comparison is used for a feedback-based adjustment of the execution of step b) and/or step c) and/or step d). Said monitoring can be for instance be provided by a direct or indirect temperature measurement of the target, preferably even a spatially resolved temperature measurement. Also detecting laser light reflected on the target can be used for such a monitoring of the properties of the laser beam impinging onto the target. By implementing a feedback-based adjustment of the execution of step b) and/or step c) and/or step d) based on said monitoring, providing a laser beam with the desired power and the desired cross section constant in time can be ensured.

The power and/or the cross section of the laser beam provided in step e) are monitored and compared to the desired power and/or the desired cross section, respectively, wherein the result of said comparison is used for a feedback-based adjustment of the execution of step b) and/or step c) and/or step d). Said monitoring can for instance be provided by a direct or indirect temperature measurement of the target, preferably even a spatially resolved temperature measurement. Also detecting laser light reflected on the target can be used for such a monitoring of the properties of the laser beam impinging onto the target. By implementing a feedback-based adjustment of the execution of step b) and/or step c) and/or step d) based on said monitoring, providing a laser beam with the desired power and the desired cross section constant in time can be ensured.

According to the second aspect of the invention, the object can be satisfied by a laser system for heating and/or evaporating and/or sublimating a target located in a reaction chamber of an evaporation system, the laser system comprising a laser light source for providing a laser beam, wherein the laser system comprises beam adjusting means comprising along the laser beam a first adjusting section, a clipping aperture with a clipping opening and a second adjusting section. The laser system according to the second aspect of the present invention is characterized in that the laser system is configured to carry out the method according to the first aspect of the present invention. Hence the laser system according to the second aspect of the present invention provides all advantages described above with respect to the method according to the first aspect of the present invention.

In particular, by carrying out the method according to the present invention, also the laser system according to the present invention can provide a total range of providable power densities at the surface of the target of a factor of more than 300 up to preferably more than 3000.

The laser system according to the present invention can be used in an evaporation system, in particular for TLE application. The laser system provides a laser beam, again preferably used in said evaporation system. The laser beam can be used for evaporating and/or sublimating a target, for example the material of a source. Alternatively, or additionally, the laser beam can also be used only for heating a target, for instance a substrate to be coated with evaporated and/or sublimated material of the source. The target is arranged within a reaction chamber, in particular in a reaction volume enclosed by the reaction chamber.

Additionally to the laser light source, the laser system comprises beam adjusting means for changing properties of the laser beam, in particular for changing at least a cross section of the laser beam. The beam adjusting means has three compulsory parts, in particular along the direction of the laser beam a first adjusting section, a clipping aperture, and a second adjusting section, respectively. The clipping aperture comprises a clipping opening, preferably centered to the laser beam. The material of the clipping aperture is preferably opaque or at least essentially opaque for the laser beam. Hence, the clipping aperture can clip the laser beam very effectively.

In particular, the laser system according to the present invention can comprise that the laser light source is configured to actively adjust the initial power and an initial cross section of the provided laser beam. By that, a first contribution to the range of providable power densities at the surface of the target can be already be provided by the laser light source. The laser source can comprise for instance laser adjusting means for changing the initial power and/or internal optical elements for varying the initial cross section. The ability to actively adjust the initial power and the initial cross section of the laser beam allows to use the same laser light source for providing different initial powers and initial cross sections respectively, of the laser beam. A need for an exchange of the laser light source for changing the initial power and the initial cross section can thereby be avoided.

In addition, the laser system according to the present invention can be characterized in that the first adjusting section is configured to actively adjust the cross section of the laser beam impinging onto the clipping aperture. In this embodiment, the first adjusting section contributes to the range of providable power densities at the surface of the target. The ability to actively adjust the cross section of the laser beam impinging onto the clipping aperture allows to use the same first adjusting sections for providing different cross sections of the laser beam at the clipping aperture. Said active adjusting can for instance be provided by adjustable lenses, mirrors or similar optical elements. An implementation of beam expanders and/or beam compressors is also possible. A need for an exchange of the first adjusting section for changing cross section of the laser beam impinging onto the clipping aperture can thereby be avoided.

Additionally, or alternatively, the laser system according to the present invention can comprise that the clipping aperture comprises an actuator for actively adjusting the size of the clipping opening. In this embodiment, the clipping aperture itself contributes to the range of providable power densities at the surface of the target. The ability to actively adjust the size of the clipping opening by an actuator allows to use the same clipping aperture for providing different sizes clipping openings. Said active adjusting can be for instance be provided by an iris diaphragm driven by the actuator. A need for an exchange of the clipping aperture for changing size of the clipping opening can thereby be avoided.

According to a preferred embodiment, the laser system according to the present invention comprises at least two, in particular three, of the following active adjustable elements:
Active adjustable laser light source
Active adjustable first adjusting section
Active adjustable clipping aperture
   By comprising two, preferably three, of said adjustable elements, the features and advantages described above with respect to the respective element can be provided in a combined matter.

Further, the laser system according to the present invention can comprise that the laser system comprises cooling means for cooling the clipping aperture. The clipping aperture is used for blocking parts of the laser beam impinging onto the clipping aperture. Hence the energy of said blocked parts of the laser beam may be, at least partially, absorbed by the bulk of the clipping aperture. By providing cooling means the bulk of the clipping aperture can be cooled, and the energy absorbed from the impinging laser beam can be transported away. Overheating the clipping aperture, which in the worst case can lead to a failure of the structural integrity of the clipping aperture, can thereby be avoided.

In addition, the laser system according to the present invention can be enhanced by that the clipping aperture comprises, preferably consists of, copper and/or aluminum alloys. Copper and aluminum comprise a comparatively high thermal conductivity of up to ˜400 W/mK (copper) and up to ˜235 W/mK (aluminum alloys). Hence a rise of a temperature of the clipping aperture is distributed particularly well over the entire clipping aperture and an effective cooling of the clipping aperture by the cooling means can be provided more easily.

Further, the laser system according to the present invention can comprise that an upstream surface of the clipping aperture facing the laser beam comprises an absorption layer for absorbing the laser beam. By providing such an absorption layer, for instance by rough plasma spray coating the upstream surface of the clipping aperture, the ability of the upstream surface of the clipping aperture for absorbing the impinging laser beam can be drastically enhanced. Damages to the laser system, the evaporation system and/or the surroundings by uncontrolled and unintentional reflections of the laser beam on the surface of the clipping aperture can thereby be avoided.

In addition, the laser system can be enhanced by that the absorption layer comprises a thickness between 100 μm to 500 μm and/or comprises, preferably consists of, aluminum oxide. Said absorption layer thickness between 100 μm to 500 μm has been found to be very effective for absorbing the impinging laser beam. In addition, especially for laser beams with a wavelength of around 10 μm, aluminum oxide provides a good to excellent absorption ability.

According to an alternative embodiment, the laser system according to the present invention can be characterized in that an upstream surface of the clipping aperture facing the laser beam is reflective for the laser beam and/or comprises a reflection layer reflective for the laser beam. In contrast to the uncontrolled and unintentional reflections mentioned above, the impinging laser beam can also be reflected on the upstream surface of the clipping aperture in a controlled and intentional way. For instance, for very high laser energies and/or densities, an absorption of the impinging laser beam by the clipping aperture might harm, even melt, the bulk material of the clipping aperture. Hence, reflecting, preferably controllably and intentionally reflecting, said impinging laser light provides a possibility to avoid absorbing an excessive amount of laser energy and hence reducing the risk of damage to the clipping aperture.

Further, the laser system according to the present invention can be enhanced by that at least a section of the upstream surface, preferably the complete upstream surface, is arranged with respect to the laser beam at an angle larger than 90°, preferably larger than 95°. Laser light reflected back into the laser light source might cause severe damage to said laser light source. By providing an angle larger than 90°, preferably larger than 95°, it especially can be ensured that laser light reflected on the upstream surface is not reflected back in the direction of the incoming laser beam and hence with a direction towards the laser light source. In addition, by providing the upstream surface at an angle with respect to the laser beam provides the possibility to control the direction of the reflected laser light, for instance towards a dedicated laser beam dump. Preferably, the upstream surface can be formed as a cone, especially as a truncated cone.

Alternatively, or additionally, the laser system according to the present invention can be enhanced by that at least a section of the upstream surface, preferably the complete upstream surface, is arranged with respect to the laser beam at an angle smaller than 90°, preferably smaller than 85°. As already pointed out above, laser light reflected back into the laser light source might cause severe damage to said laser light source. By providing an angle smaller than 90°, preferably smaller than 85°, it especially can be ensured that laser light reflected on the upstream surface is not reflected back in the direction of the incoming laser beam and hence with a direction towards the laser light source. In addition, by providing the upstream surface at an angle with respect to the laser beam provides the possibility to control the direction of the reflected laser light, for instance towards a dedicated laser beam dump. Preferably, the upstream surface can be formed as a cone, especially as a truncated cone.

In another embodiment, the laser according to the present invention can comprise that the laser source and/or the first adjusting section provides an at least essentially parallel laser beam. A parallel laser beam can be beneficial, in particular as distances between optical elements can be varied without changing the properties of the laser beam. For instance, the laser light source can be positioned distanced, especially in a different room or even in a different building, to the remaining parts of the laser system, which might be assembled to the reaction chamber of the evaporation system. A flexibility with respect to the setup of the laser system according to the present invention can thereby be improved.

In addition, the laser system according to the present invention can be characterized in that the second adjusting section comprises a focusing lens focusing the laser beam towards the surface of the target. A focusing lens as part of the second adjusting section after the clipping aperture provides a focus and images the laser beam to the working plane where the target is located, especially independent of the size of the clipping opening. In the scope of the present invention, focusing the laser beam towards the surface of the target includes both, focusing directly onto the target surface and focusing between target surface and focusing lens. In the first case, a focal volume representing the smallest extent of the beam is located at or at least in the vicinity of the target surface, in the latter case said focal volume is arranged somewhere in between the focusing lens and the target surface. The actual position of the focal volume can thereby be chosen according to the boundary conditions present in the respective evaporation system.

In yet another embodiment, the laser system according to the present invention can comprise that in a mounted state the beam adjusting means are at least partially arranged within the reaction chamber. As the target is also arranged within the reaction chamber, in ascending order parts of or the whole second adjusting section, additionally the clipping aperture, and again additionally parts of or the whole first adjusting section are arranged within the reaction chamber. In summary, as the reaction chamber requires in any case a certain construction space, arranging a part of the adjusting means within the reaction chamber helps reducing the needed construction space for the evaporation system as a whole.

In addition, the laser system according to the present invention can be enhanced by that the second adjusting section comprises a shielding aperture with a shielding opening arranged within the reaction chamber, wherein a focal volume of the laser beam is arranged at the shielding opening. In other words, the shielding aperture is arranged within the reaction chamber between the coupling means in the chamber wall of the reaction chamber, for instance a chamber window, and the target. In particular, the focal volume of the laser beam, preferably generated by a focusing lens as part of the second adjusting section, which represents the smallest extent of the laser beam along its path, is arranged at the shielding opening of the shielding aperture. Thereby, a direct line of sight between the target surface and the coupling means is almost completely blocked with exception of the shielding opening. Hence, material of the target evaporated and/or sublimated by the impinging laser light will mostly impinge onto the shielding aperture and the coupling means is protected against unintentional coating. A life time of said coupling means can thereby be extended drastically.

In a further embodiment, the laser system can be characterized in that in a mounted state the beam adjusting means is arranged outside of the reaction chamber along the laser beam at least up to the focusing lens. The focusing lens is part of the second adjusting section. In other words, the complete first adjusting section and the clipping aperture, the two parts of the beam adjusting means used for clipping the laser beam, in particular as set in step c) of the method according to the first aspect of the present invention, are arranged outside of the reaction chamber and hence easily accessible.

Additionally, in most of the embodiments of the evaporation system the focusing lens is arranged outside, but nevertheless in short distance to the coupling means of the reaction chamber. Directly after the focusing lens the cross section of the laser beam is still comparatively large and hence the power density is respectively low. This results in low heating and long uptime of the coupling means.

Further, the laser system according to the present invention can comprise that the first adjusting section and/or the second adjusting section comprises one or more of the following optical elements:
focusing lens and/or mirror
defocusing lens and/or mirror
free-form mirror
beam expander
beam compressor
focusing axicon
defocusing axicon
   This list is not closed and also other optical elements as part of the first adjusting section and/or the second adjusting section are possible. By implementing different optical elements, a wide variety of possible parameters of the laser beam at the target surface, such as for instance an overall shape or a spatially dependent intensity distribution, can be provided.

According to another embodiment, the laser system according to the present invention can be characterized in that the laser system comprises one or more additionally secondary beam adjusting means successively arranged in series along the laser beam after the beam adjusting means. Likewise to the beam adjusting means described above, also each of the one or more additionally secondary beam adjusting means comprise a first adjusting section, a clipping aperture, and a second adjusting section, respectively. Also, the functions of these elements are the same as of the elements of the adjusting means described above. Hence, each of the secondary adjusting means receives an incoming laser beam with an initial power and an initial cross section and provides a laser beam with a desired power and a desired cross section, whereby the initial power and the initial cross section corresponds to the desired power and the desired cross section of the previous beam adjusting means along the laser beam. The last secondary beam adjusting means finally provides the laser beam with the desired power and the desired cross section at the surface of the target. In summary, by arranging several beam adjusting means in series along the path of the laser beam, the providable total ranges of power densities of each of the beam adjusting means multiply. For instance, if a single secondary beam adjusting means with a providable range of a factor of more than 250 is used in series with a beam adjusting means with a providable range of a factor of more than 500, in total a providable range of laser power of a factor of more than 125000 can be provided.

According to the third aspect of the invention, the object can be satisfied by an evaporation system for coating a substrate with evaporated and/or sublimated material of a source, comprising a reaction chamber with a reaction volume for arranging the source and the substrate, and a substrate laser system for heating the substrate and/or a source laser system for evaporating and/or sublimating material of the source. The evaporation system according to the third aspect of the present invention is characterized in that the substrate laser system and/or the source laser system is a laser system according to the second aspect of the present invention. In other words, the substrate laser system and/or the source laser system can be used to run a method according to the first aspect of the present invention. Hence, the evaporation system according to the third aspect of the present invention provides all advantages described above with respect to the laser system according to the second aspect of the present invention, and also with respect to the method according to the first aspect of the present invention.

The invention will be explained in detail in the following by means of embodiments and with reference to the drawings in which are shown:

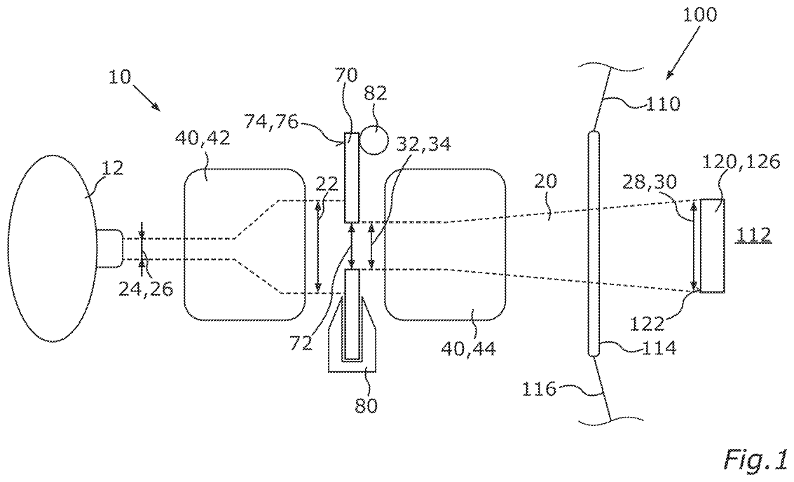

FIG. 1 A first embodiment of an evaporation system according to the present invention,

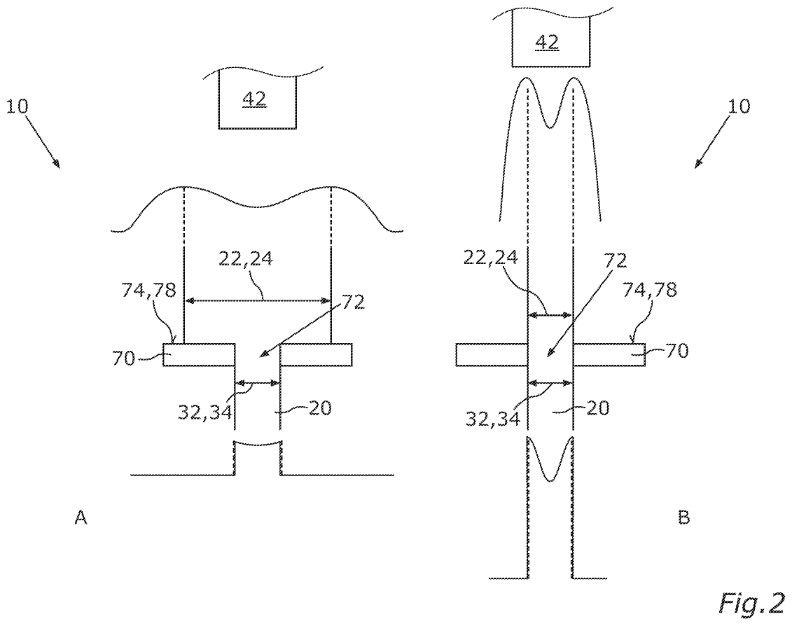

FIG. 2 The interplay of the first adjusting section and the clipping aperture,

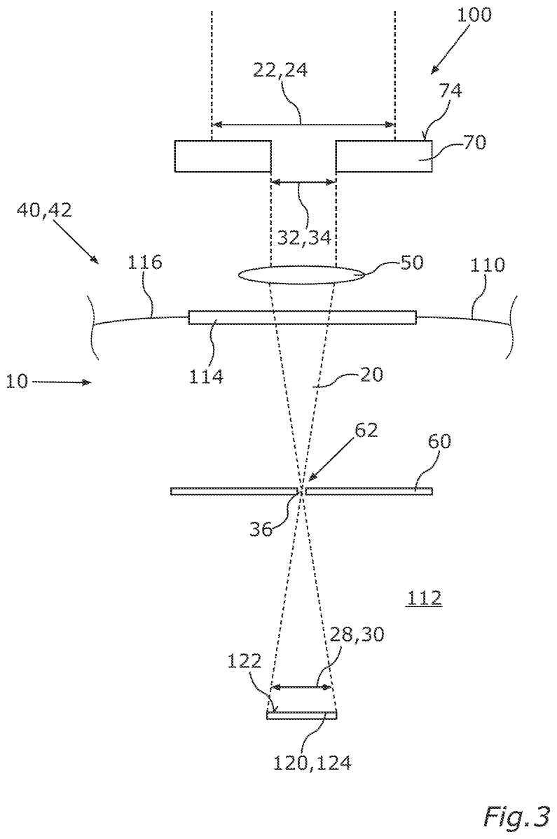

FIG. 3 A second embodiment of an evaporation system according to the present invention, and

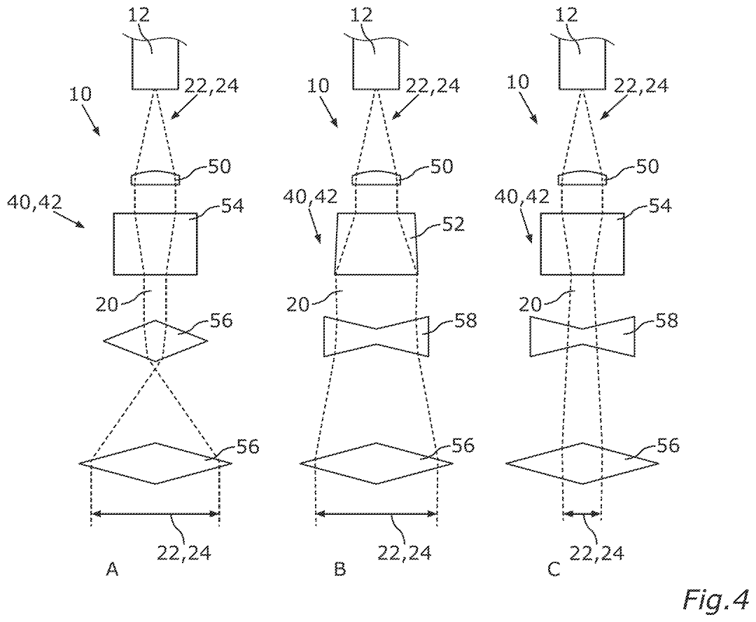

FIG. 4 Three examples of optical elements used in the first adjusting section.

FIG. 1 schematically depicts a possible embodiment of an evaporation system 100 according to the present invention. Said evaporation system 100 comprises a laser system 10 according to the present invention, which is used for heating a target 120, in particular a substrate 126 to be coated. Both the evaporation system 100 and the laser system 10, respectively, are configured for carrying out the method according to the present invention. The target 120 is arranged within a reaction chamber 110, in particular in a reaction volume 112 enclosed by the reaction chamber 110.

In the depicted embodiment, the laser system 10 is arranged completely outside of the reaction chamber 110. The laser system 10 at least comprises a laser light source 12 and beam adjusting means 40, which in turn at least comprise a first adjusting section 42, a clipping aperture 70 and a second adjusting section 44. The laser beam 20 provided by the laser system 10 is guided into the reaction chamber 110 through coupling means 114 arranged in a chamber wall 116 of the reaction chamber 110. Said coupling means 114 is for instance a chamber window.

It is the intention of the present invention to provide the laser beam 20 at the surface 122 of the target 120 with a desired power 28 and a desired cross section 30. In the following, said method according to the present invention is described based on the embodiment of the evaporation system 100 depicted in FIG. 1. However, this description is by way of example only and is not limiting as to the content of the invention.

In a first step a) of the method according to the present invention, said desired power 28 and desired cross section 30 are determined. The desired power 28 and the desired cross section 30 preferably a chosen suitable for the purpose of the laser beam 20, namely on the one hand heating and on the other hand evaporating and/or sublimating. In addition, the material to be heated, evaporated or sublimated, respectively, can be considered when determining the desired power 28 and the desired cross section 30. The determined values are subsequently used for setting the laser system 10 and hence the complete evaporation system 100.

First of all, in step b) of the method according to the present invention, the laser light source 12 of the laser system 10 is set to provide a laser beam 20 with an initial power 24 and an initial cross section 26. Preferably, the initial power 24 is set between 10% and 100%, in particular 5% and 100, preferably 3% and 100%, of a maximum power providable by the laser light source 12. Already by setting said initial power 24, and in particular also the initial cross section 26, a variation of values of the desired power 28 and the desired cross section 30 providable by the laser system 10 according to the present invention can be provided. Preferably, the laser light source 12 is configured to actively adjust said initial power 24 and an initial cross section 26, allowing a usage of the same laser light source 12 for providing laser beams 20 with different initial properties.

Along the direction of the laser beam 20, the next element of the laser system 10 is a first adjusting section 42. Said first adjusting section 42 can at least alter the cross section 22 of the laser beam 20, in particular enlarge said cross section 22.

By enlarging the cross section 22, the total power of the laser beam 20 essentially stays unaffected, and hence a power density of the laser beam 20 can be altered, in particular lowered. In other words, the fraction of the total power of the laser beam 20 impinging onto a certain area can be adjusted, in particular lowered.

Preferably, the adjustment of the cross section 22 of the laser beam 20 described above can be provided by the first adjusting section 42 in an active way. Said active adjusting can be for instance be provided by adjustable lenses, mirrors or similar optical elements. Actively adjusting the laser beam 20 by the first adjusting section 42 allows using the laser system 10 according to the present invention for different desired powers 28 and/or desired cross sections 30 without the need of exchanging the first adjusting section 42.

As depicted, both the laser source 12 and the first adjusting section 42, respectively, provide an at least essentially parallel laser beam 20. Hence, the distances between the laser light source 12 and the first adjusting section 42, and between the first adjusting section 42 and the clipping aperture 70, have no or at least no essential impact on the optical properties of the laser system 10.

Again, after the first adjusting section 42, a clipping aperture 70 is arranged along the path of the laser beam 20. Said clipping aperture 70 comprises a clipping opening 72. In most of the cases, the clipping opening 72 comprises a smaller size than the laser beam 20 after passing the first adjusting section 42. Hence, only a fraction of the impinging laser beam 20 passes through the clipping opening 72, the remaining laser beam 20 impinges onto an upstream surface 74 of the bulk of the clipping aperture 70. As depicted, the clipping aperture 70 can comprise an actuator 80 for actively adjusting the size of the clipping aperture 72. Hence aforementioned fraction of the laser beam 20 passing through the clipping aperture 70 can also be adjusted by the clipping aperture 70 itself.

In the depicted embodiment, the upstream surface 74 is coated with an absorption layer 76 for absorbing the laser beam 20, for instance by rough plasma spray coating the upstream surface 74 of the clipping aperture 70. Preferably, said absorption layer 76 comprises a thickness between 100 μm and 500 μm. Additionally, or alternatively, the absorption layer 76 comprises, preferably consists of, aluminum oxide. Absorbing the impinging laser beam 20 by said absorption layer 76 helps avoiding damages to the laser system 20, the evaporation system 100 and/or the surroundings by uncontrolled and unintentional reflections of the laser beam 20 on the upstream surface 74 of the clipping aperture 70.

As the energy of the absorbed laser beam 20 heats the bulk of the clipping aperture 70, a cooling means 82 is provided for cooling the clipping aperture 70. For instance, for laser beams 20 with very high laser energies and/or densities, an absorption of the impinging laser beam 20 by the clipping aperture 70 might harm, even melt, the bulk material of the clipping aperture 70. Actively cooling the clipping aperture 70 by the cooling means 82 prevents said dangers. Thermal conductivity of the clipping aperture 70 can be enhanced by the clipping apertures 70 comprising, preferably consisting of, copper and/or aluminum alloys.

As mentioned above, the first adjusting section 42 provides the laser beam 20 with a certain power density. In addition, the size of the clipping aperture 72 defines the fraction of the impinging laser beam 20 passing through the clipping aperture 70. Together, these two elements of the laser system 10 according to the present invention define the fraction of the total power of the laser beam 20 still present after the clipping aperture 70. Preferably, said fraction of the laser beam 20 shining through the clipping opening 72 is provided between 100% and less than 3%, in particular 100% and less than 2%, preferably 100% and less than 1%, of the laser beam 20 impinging on the clipping aperture 70. Considering that also the laser light source 12 can contribute to the range of providable power densities a factor of 10, in particular 20, preferably more than 30, a total range of providable power densities of a factor of more than 300 up to preferably more than 3000 can be provided by running a laser system 10 according to the present invention by a method according to the present invention.

In particular, this remaining power of the laser beam 20 is provided in step c) of the method according to the present invention by defining the interplay of the first adjusting section 42 and the clipping aperture 42 by setting said elements of the laser system 10. In particular, the laser beam 20 is provided with an intermediate power 32 chosen such that it can be ensured that the laser beam 20 comprises at least, preferably exactly, the desired power 28 at the target. Preferably, the intermediate power 32 is chosen such that the expected power losses of the laser beam 20 along its path between the clipping aperture 70 and the target 120 are compensated, in other words that the intermediate power 32 equals the sum of the desired power 28 and said expected power losses. The accompanied intermediate cross section 34 of the laser beam 20 is defined by and corresponds to the size of the clipping opening 72.

Essentially, except for the power losses mentioned above, the power of the laser beam 20 is set after the clipping aperture 70. Hence, the second adjusting section 44 arranged along the laser beam 20 between the clipping aperture 70 and the target 120, is in general responsible for transforming the intermediate cross section 34 of the laser beam 20 into the desired cross section 30 of the laser beam 20 at the target 120. The setting of the second adjusting section 44 for said transformation of the cross section of the laser beam 20 is provided in step d) of the method according to the present invention.

Finally, in the last mandatory step e) of the method according to the present invention, the laser light source 12 is switched on and the laser beam 20 is actually provided to the target 120. As all settings described above are done, namely the settings of the first adjusting section 42, of the clipping aperture 70, and of the second adjusting section 44, respectively, the laser beam 20 is provided at the surface 122 of the target 120 with both the desired power 28, and the desired cross section 30, respectively.

Considering that in addition to the adjusting means 40 also the laser light source 12 can contribute to the range of providable power densities, a total range of providable power densities at the target of a factor of more than 300 up to preferably more than 3000 can be provided by running a laser system 10 according to the present invention by a method according to the present invention.

In addition, the method according to the present invention can also comprise an additional step f), in which a feedback-based adjustment of the aforementioned settings is carried out. The feedback can be based on a comparison of the actual power 22 and/or the cross section of the laser beam 20 provided at the target 120 to the desired power 28 and/or the desired cross section 30, respectively, which can be monitored for instance by a direct or indirect temperature measurement of the target 120, or by detecting laser light reflected on the surface 122 of the target.

In FIG. 2. the interplay of the first adjusting section 42 (see FIG. 1) and the clipping aperture 70 is depicted for two examples. In the panel A on the left a laser beam 20 is provided with a comparatively low intermediate power 32, in panel B on the right with a comparatively high intermediate power 32. In both panels A, B, the laser beam 20 comprises the same initial power 24, and additionally the clipping opening 72 comprises the same size.

However, both panels A, B differ in particular by the cross section 22 of the laser beam 20 provided by the first adjusting section 42. In panel A, the laser beam 20 comprises a comparatively large cross section 22. In contrast to that, in panel B the laser beam 20 comprises a comparatively small cross section 22. Accordingly, only a small fraction of the laser beam 20 impinging in panel A on the upstream surface 74 of the clipping aperture 70 can pass through the clipping opening 72. In contrast to that, in panel B a huge fraction of the incoming laser beam 20 passes through the clipping opening 72 and is still available after the clipping aperture 70 as a laser beam with a high intermediate power 32 and an intermediate cross section 34 defined by the size of the clipping opening 72.

Additionally, in contrast to the embodiment of the clipping aperture 70 depicted in FIG. 1, in both panels A, B of FIG. 2 the upstream surface 74 of the clipping aperture 70 comprises a reflective layer 78 and thereby is reflective for the laser beam 20. Thereby the laser beam 20 impinging on the upstream surface 74 can be intentionally reflected and the aforementioned drawback of heating the bulk material of the clipping aperture 70 by absorbing laser light 20 can be avoided. In the schematic view of FIG. 2, the upstream surface 74 is arranged essential perpendicular to the laser beam 20. However, it is preferred to arrange the upstream surface 74 with respect to the laser beam 20 at an angle different from 90°, in particular 5° or more smaller or larger than 90°.

FIG. 3 depicts another embodiment of the evaporation system 100 according to the present invention with a laser system 10 according to the present invention. In particular, FIG. 3 focuses on the second adjusting section 44 of said laser system 10.

As is clearly visible, the second adjusting section 44, and hence the adjusting means 40, are partially arranged within the reaction chamber 110. A focusing lens 50 is arranged adjacent outside of the coupling means 114. The focusing lens 50 focuses the laser beam 20 provided after the clipping aperture 70, and hence comprising the intermediate power 32 and the intermediate cross section 34, towards the surface 122 of the target 120. Again, the clipping aperture 70 blocks a fraction of the incoming laser beam 20 comprising the initial power, as the clipping opening 72 is smaller than the cross section 22 of the laser beam 20 impinging on the upstream surface 74 of the clipping aperture 70.

In the depicted embodiment, the target 120 forms a source 124. During evaporation and/or sublimation of material of the source 124 by the laser beam 20, said material also propagates towards the coupling means 114. For preventing an unintentional and especially uptime-shortening coating of the coupling means 114, as depicted a shielding aperture 60 can be arranged within the reaction chamber 110 between the coupling means 114 and the target 120. The focal volume 36 provided by the aforementioned focusing lens 50 is positioned such that it coincides with the shielding opening 62 of the shielding aperture 60. Thereby most of the material of the source 124 travelling towards the coupling means 114 are blocked by the shielding aperture 60.

Panels A, B and C of FIG. 4 depict different possible embodiments of the laser system 10 according to the present invention, especially of the first adjusting section 42 of the adjusting means 40. In particular, each of the depicted embodiments comprises axicons 56, 58 for providing laser beams 20 with a spatially dependent power distribution as depicted in FIG. 2. Additional elements are focusing lenses 50, beam expanders 52 or beam compressors 54. The depicted embodiments are examples and are not limiting the possible internal structures of the respective first adjusting sections 42 of the laser systems 10 according to the present invention.

In particular, in the depicted embodiments the respective first adjusting section comprises the following optical elements:
Embodiment “A”: focusing lens 50, beam compressor 54, first focusing axicon 56, second focusing axicon 56
Embodiment “B”: focusing lens 50, beam expander 52, defocusing axicon 58, focusing axicon 56
Embodiment “C”: focusing lens 50, beam compressor 54, defocusing axicon 58, focusing axicon 56

The depicted embodiments are to be understood as examples only. For instance, the focusing axicons 56 in embodiments “A”, “B” and “C” can alternatively be replaced by a focusing lens 50 (not depicted). Further, a beam compressor 54 can also be used as beam expander 52 when arranged inverted with respect to the path of the laser beam 12, and vice versa.

### LIST OF REFERENCES

10 Laser system
12 Laser light source
20 Laser beam
22 Cross section
24 Initial power
26 Initial cross section
28 Desired power
30 Desired cross section
32 Intermediate power
34 Intermediate cross section
36 Focal volume
40 Beam adjusting means
42 First adjusting section
44 Second adjusting section
50 Focusing lens
52 Beam expander
54 Beam compressor
56 Focusing axicon
58 Defocusing axicon
60 Shielding aperture
62 Shielding opening
70 Clipping aperture
72 Clipping opening
74 Upstream surface
76 Absorption layer
78 Reflection layer
80 Actuator
82 Cooling means
100 Evaporation system
110 Reaction chamber
112 Reaction volume
114 Coupling means
116 Chamber wall
120 Target
122 Surface
124 Source
126 Substrate

1-26. (canceled)

27. A method of running a laser system for providing a laser beam capable of heating and/or evaporating and/or sublimating a target located in a reaction chamber of an evaporation system, the laser system comprising a laser light source for providing a laser beam, and beam adjusting means for adjusting at least the cross section of the laser beam, the beam adjusting means comprising along the laser beam a first adjusting section, a clipping aperture with a clipping opening and a second adjusting section, comprising the steps of:
a) Determining a desired power of the laser beam and a desired cross section of the laser beam to be provided at the surface of the target,
b) Setting the laser light source for providing the laser beam with an initial power and an initial cross section,
c) Setting the first adjusting section and/or the clipping opening based on the initial power, the initial cross section and the desired power, for providing the laser beam after shining through the clipping opening with an intermediate power matched to the desired power,
d) Setting the second adjusting section for providing the laser beam with the desired power and the desired cross section at the surface of the target, and
e) Providing the laser beam by the laser light source set in step b), and subsequently adjusting the laser beam by the beam adjusting means set in steps c) and d) for providing the laser beam with the desired power and the desired cross section, respectively, set in step a) at the surface of the target.

28. The method according to claim 27,
wherein the intermediate power of the laser beam provided after the clipping opening corresponds to a sum of the desired power and expected power losses in the second adjusting section.

29. The method according to claim 27,
wherein in step b) the initial power is set between 10% and 100% of a maximum power providable by the laser light source.

30. The method according to claim 27,
wherein in step c) the first adjusting section is set to enlarge the cross section of the laser beam for reducing the fraction of the laser shining through the clipping opening.

31. The method according to claim 27,
wherein in step c) the clipping aperture is set to reduce the clipping opening for reducing the fraction of the laser beam shining through the clipping opening.

32. The method according to claim 30,
wherein the fraction of the laser beam shining through the clipping opening is provided between 100% and less than 3% of the laser beam impinging on the clipping aperture.

33. The method according to claim 27,
wherein in an additional step f) the power and/or the cross section of the laser beam provided in step e) are monitored and compared to the desired power and/or the desired cross section, respectively, and wherein the result of said comparison is used for a feedback-based adjustment of the execution of step b) and/or step c) and/or step d).

34. Laser system for heating and/or evaporating and/or sublimating a target located in a reaction chamber of an evaporation system, the laser system comprising a laser light source for providing a laser beam, wherein the laser system comprises beam adjusting means comprising along the laser beam a first adjusting section, a clipping aperture with a clipping opening and a second adjusting section, and wherein the laser system is configured to carry out the method according to claim 27.

35. Laser system according to claim 34,
wherein the laser light source is configured to actively adjust the initial power and an initial cross section of the provided laser beam.

36. Laser system according claim 34,
wherein the first adjusting section is configured to actively adjust the cross section of the laser beam impinging onto the clipping aperture.

37. Laser system according to claim 34,
wherein the clipping aperture comprises an actuator for actively adjusting the size of the clipping opening.

38. Laser system according to claim 34,
wherein the laser system comprises cooling means for cooling the clipping aperture.

39. Laser system according to claim 38,
wherein the clipping aperture comprises copper and/or aluminum alloys.

40. Laser system according to claim 34,
wherein an upstream surface of the clipping aperture facing the laser beam comprises an absorption layer for absorbing the laser beam.

41. Laser system according to claim 40,
wherein the absorption layer comprises a thickness between 100 μm to 500 μm and/or comprises aluminum oxide.

42. Laser system according to claim 34,
wherein an upstream surface of the clipping aperture facing the laser beam is reflective for the laser beam and/or comprises a reflection layer reflective for the laser beam.

43. Laser system according to claim 42,
wherein at least a section of the upstream surface is arranged with respect to the laser beam at an angle larger than 90°.

44. Laser system according to claim 42,
wherein at least a section of the upstream surface is arranged with respect to the laser beam at an angle smaller than 90°.

45. Laser system according to claim 34,
wherein the laser source and/or the first adjusting section provides an at least essentially parallel laser beam.

46. Laser system according to claim 34,
wherein the second adjusting section comprises a focusing lens focusing the laser beam towards the surface of the target.

47. Laser system according to claim 34,
wherein in a mounted state the beam adjusting means are at least partially arranged within the reaction chamber.

48. Laser system according to claim 47,
wherein the second adjusting section comprises a shielding aperture with a shielding opening arranged within the reaction chamber, wherein a focal volume of the laser beam is arranged at the shielding opening.

49. Laser system according to claim 46,
wherein in a mounted state the beam adjusting means is arranged outside of the reaction chamber along the laser beam at least up to the focusing lens.

50. Laser system according to claim 34,
wherein the first adjusting section and/or the second adjusting section comprises one or more of the following optical elements:
focusing lens and/or mirror
defocusing lens and/or mirror
free-form mirror
beam expander
beam compressor
focusing axicon
defocusing axicon

51. Laser system according to claim 34, wherein the laser system comprises one or more additionally secondary beam adjusting means successively arranged in series along the laser beam after the beam adjusting means.

52. Evaporation system for coating a substrate with evaporated and/or sublimated material of a source, comprising a reaction chamber with a reaction volume for arranging the source and the substrate, and a substrate laser system for heating the substrate and/or a source laser system for evaporating and/or sublimating material of the source,
wherein the substrate laser system and/or the source laser system is a laser system according to claim 34.

53. A method of running a laser system for providing a laser beam capable of heating and/or evaporating and/or sublimating a target located in a reaction chamber of an evaporation system, the laser system comprising a laser light source for providing a laser beam, and a beam adjustor configured to adjust at least the cross section of the laser beam, the beam adjustor comprising along the laser beam a first adjusting section, a clipping aperture with a clipping opening and a second adjusting section, comprising the steps of:
a) Determining a desired power of the laser beam and a desired cross section of the laser beam to be provided at the surface of the target,
b) Setting the laser light source for providing the laser beam with an initial power and an initial cross section,
c) Setting the first adjusting section and/or the clipping opening based on the initial power, the initial cross section and the desired power, for providing the laser beam after shining through the clipping opening with an intermediate power matched to the desired power,
d) Setting the second adjusting section for providing the laser beam with the desired power and the desired cross section at the surface of the target, and
e) Providing the laser beam by the laser light source set in step b), and subsequently adjusting the laser beam by the steps in c) and d) for providing the laser beam with the desired power and the desired cross section, respectively, set in step a) at the surface of the target.
